(19) United States
(12) Patent Application Publication
(10) Pub. No.: US 2024/0379573 A1
(43) Pub. Date: Nov. 14, 2024

(54) SEMICONDUCTOR ASSEMBLY COMPRISING AT LEAST TWO SEMICONDUCTOR ELEMENTS

(71) Applicant: Siemens Aktiengesellschaft, 80333 München (DE)

(72) Inventors: MICHAEL ENDRES, Schesslitz (DE); ROBERT GOSPOS, Buckenhof (DE); BERND KÜRTEN, Obermichelbach (DE); FELIX ZEYSS, Erlangen (DE)

(73) Assignee: Siemens Aktiengesellschaft, 80333 München (DE)

(21) Appl. No.: 18/691,318

(22) PCT Filed: Aug. 5, 2022
(86) PCT No.: PCT/EP2022/072137

§ 371 Date: Mar. 12, 2024

(30) Foreign Application Priority Data
Sep. 30, 2021 (EP) 21200047.5

(51) Int. Cl. H01L 23/538; H01L 23/00; H01L 23/373; H01L 23/64; H01L 25/07

(52) U.S. Cl. CPC H01L 23/5386; H01L 23/647; H01L 24/48; H01L 24/49; H01L 23/3735; H01L 25/072; H01L 2224/48137; H01L 2224/48139; H01L 2224/48177; H01L 2224/49171; H01L 2924/13055

(57) ABSTRACT

A semiconductor assembly includes semiconductor elements connected to a first conductor track of a substrate. A current path impedance is embodied from each semiconductor element to a connection element. A first bond connector connects a contact surface on a substrate-distal side of each semiconductor element to a second conductor track of the substrate. Electrically conductive parallel connections transverse to a current direction connect the second conductor track to a third conductor track of the substrate. The third conductor track is connected to the connection element. The electrically conductive connections are dimensioned and/or arranged to substantially balance the current path impedances of the current paths from the semiconductor elements to the connection element. A second bond connector connects the third conductor track to the connection element. The second and third conductor tracks of the substrate each have a measurement tap to detect a current through the electrically conductive connections.

The invention relates to a semiconductor assembly comprising at least two semiconductor elements that are in particular connected in parallel, an insulating substrate and a connection element.

The invention further relates to a semiconductor module with at least one such semiconductor assembly.

Over and above this the invention relates to a power converter with at least one such semiconductor assembly.

What is more, the invention further relates to a method for producing a semiconductor assembly comprising at least two semiconductor elements that are in particular connected in parallel, an insulating substrate and a connection element.

Such a semiconductor assembly is used as a rule in a semiconductor module, which is installed in a power converter. A power converter is to be understood for example as a rectifier, an ac converter, an inverter or a do voltage converter. The semiconductor elements used in the semiconductor module include elements such as transistors, triacs, thyristors or diodes. Transistors are for example embodied as Insulated-Gate-Bipolar-Transistors (IGBTs), field effect transistors or bipolar transistors. In such semiconductor modules a number of semiconductor elements, in particular semiconductor switching elements, arranged on a substrate can be used, wherein a geometrical course of a load current through the respective semiconductor elements is dependent on a plurality of factors, which include the arrangement of the semiconductor elements and also how they are contacted with the substrate.

A flow of current through parallel switched semiconductor elements can be at least slightly different, so that a power loss is not distributed evenly to the semiconductor elements, whereby so-called hotspots are formed. This is responsible for a reduction in a service life of the assembly as a whole, since the service life is limited by the maximum semiconductor temperature that occurs. A similar effect further comes to light when a number of semiconductor elements are connected in a semiconductor assembly to form a functional circuit. During operation the load current is flowing through various semiconductors at different times. Since these are located spatially separately from one another, the geometrical path of the current flow also changes over the course of time. Through different current paths a result can be that, as a result of different parasitic impedances, in particular parasitic resistances and/or parasitic inductivities are produced for the different switching states, from which an uneven switching behavior of the various semiconductors is produced. Over and above this, inter alia a measurement facility with an ohmic resistance for detection of a load current can lead to an influence of the measurement and/or of the load current itself, in particular dependent on a switching state of the semiconductor elements.

The unexamined patent DE 10 2012 220 127 A1 describes a semiconductor apparatus with a housing and a semiconductor switch element, which is provided in the housing, and which has a collector electrode and an emitter electrode. A main connector connection and a main emitter connection reflect a voltage drop, which is created during the application of a current by an ungrounded component in the housing. A second collector electrode and a second emitter electrode detect a voltage between the collector electrode and the emitter electrode, without reflecting the voltage drop. A third emitter connection is arranged in the vicinity of the second emitter connection and detects the voltage drop generated between the main emitter connection and the second emitter connection.

Unexamined patent application US 2002/024135 A1 describes a wiring pattern and conductor wires not relaying a wiring pattern fed with an emitter current connect emitter electrodes of a plurality of IGBTs connected in parallel to each other. Thus the occurrence of oscillations on the potential of a control electrode of the plurality of IGBTs is suppressed.

The patent application DE 10 2014 102018 B3 describes a power semiconductor module with internal load and auxiliary connection facilities, which are embodied as wired connections. A substrate has a plurality of load and auxiliary potential surfaces, wherein a power switch is arranged on a first load potential surface, which is embodied as a plurality of controllable power sub-switches arranged in series. The power sub-switches have a load bond connection consisting of a plurality of load bond wires, with a second load potential surface, wherein a first bond foot is arranged on the second load potential surface and a neighboring second bond foot of the respective load bond wire is arranged on a contact surface of the power sub-switch.

Against this background, the underlying object of the invention is to specify a semiconductor assembly, which, by comparison with the prior art, achieves a longer service life and is lower-cost.

The object is achieved in accordance with the invention by a semiconductor assembly comprising at least two semiconductor elements, that are in particular connected in parallel, by an insulating substrate and a connection element, wherein the substrate has conductor tracks electrically insulated from one another, wherein the semiconductor elements are connected, in particular in an integrally bonded manner, to a first conductor track of the substrate and have at least one contact surface on a side facing away from the substrate in each case, wherein in each case at least one contact surface of the semiconductor elements is connected via first bond connection means to a second conductor track of the substrate, wherein the second conductor track is connected by electrically conductive connection means to a third conductor track of the substrate, wherein the third conductor track is connected to the connection element, wherein a current path with a current path impedance is embodied from the semiconductor elements to the connection element in each case, wherein the electrically conductive connection means are dimensioned and/or arranged in such a way that the current path impedances of the respective current paths are substantially balanced, wherein the electrically conductive connection means are arranged connected in parallel and transverse to a current direction, wherein the second conductor track and the third conductor track each have a measuring tap, which is configured to detect a current through the shunt resistors and/or third bond connection means connected in parallel.

The object is further achieved in accordance with the invention by a semiconductor module with at least one such semiconductor assembly.

Besides this, the object is achieved in accordance with the invention by a power converter with at least one such semiconductor assembly.

Over and above this the object is achieved in accordance with the invention by a method for producing a semiconductor assembly comprising at least two semiconductor elements that are in particular connected in parallel, by an insulating substrate and a connection element, wherein the substrate has conductor tracks electrically insulated from one another, wherein the semiconductor elements are connected, in particular in a materially-bonded manner, to a first conductor track of the substrate and have at least one contact surface on a side facing away from the substrate in each case, wherein in each case at least one contact surface of the semiconductor elements is connected via first bond connection means to a second conductor track of the substrate, wherein the second conductor track is connected by electrically conductive connection means to a third conductor track of the substrate, wherein the third conductor track is connected to the connection element, wherein a current path with a current path impedance is embodied from the semiconductor elements to the connection element in each case, wherein the electrically conductive connection means are dimensioned and/or arranged in such a way that the current path impedances of the respective current paths are substantially balanced, wherein the electrically conductive connection means are arranged connected in parallel and transverse to a current direction, wherein the second conductor track and the third conductor track each have a measuring tap, wherein a current passing through the shunt resistors connected in parallel and/or the third bond connection means is detected by the measuring taps,

The advantages and preferred forms of embodiment stated here with regard to the semiconductor assembly are able to be transferred by analogy to the semiconductor module, the power converter and the method,

The underlying idea behind the invention is to increase the service life of a semiconductor assembly, in that current paths of at least two semiconductor elements of the semiconductor assembly are symmetrized by balancing of current path impedances by means of dimensioning and/or arrangement of electrically conductive connection means. Since the service life of the semiconductor elements is limited by the maximum semiconductor temperature occurring, an even heating of the semiconductor elements is achieved by such a symmetry between the respective current path impedances. Such a semiconductor assembly can be arranged inter alia in a semiconductor module or can be connected directly to a heat sink of a power converter. The at least two semiconductor elements are embodied for example as transistors, in particular as Insulated-Gate Bipolar Transistors (IGBTs), and optionally each have an antiparallel diode. As an alternative the semiconductor elements can be embodied, inter alia, as further transistor types, such a field effect transistors or bipolar transistors. The semiconductor elements can further be connected in parallel and/or connected together into a functional circuit, for example a half bridge.

Furthermore the semiconductor assembly comprises an insulating substrate and a connection element, wherein the substrate has conductor tracks insulated electrically from one another. The substrate can be embodied for example as a DCB substrate (Direct Copper Bonded) substrate. The semiconductor elements are connected, in particular in a materially-bonded manner, to a first conductor track of the substrate. The semiconductor elements each further have, on a side facing away from the substrates, at least one contact surface. Such contact surfaces are inter alia metallic pads that are suitable for making contact with bond connection means. For example the contact surfaces are embodied as emitter or source pads. One contact surface of the semiconductor elements in each case is connected via a first bond connection means to a second conductor track of the substrate. The first bond connection means for example comprises bond wires and/or bond tapes, which are substantially arranged in parallel to one another. The second conductor track is connected via electrically conductive connection means to a third conductor track of the substrate. The electrically conductive connection means can inter alia have resistance elements and/or inductors which are connected for example to the second conductor track and third conductor track in a materially-bonded manner. The third conductor track is connected to the connection element, for example via bond connection means, The connection element is configured for example for a connection to a busbar. The semiconductor elements each form a current path to the connection element with a current path impedance. The current path impedances can be differentiated from one another inter alia due to different resistances of the semiconductor elements, resistances of bond connection means in the current path, line lengths and/or contact resistances. The electrically conductive connection means, which connect the second conductor track to the third conductor track, are dimensioned and/or arranged in such a way that the current path impedances of the respective current paths are substantially balanced. For example an electrical resistance of electrically conductive connection means embodied as resistance elements is adapted so that the respective current path impedances are made symmetrical. An asymmetrical connection of the connection element can likewise be balanced in this way. As well as increasing the service life, furthermore cost savings are made, since with an even, in particular thermal, loading, smaller and thus better semiconductor elements can be used. Through the use of smaller semiconductor elements said elements are able to be positioned more flexibly on the substrate, so that there can be improved heat dissipation, which additionally has a positive influence on the service life.

The electrically conductive connection means are connected in parallel and arranged transverse to a current direction. Through such an arrangement the respective current path impedances can be made symmetrical in a simple and reproducible way.

The second conductor track and the third conductor track each have a measurement tap, which are configured for detection of a current passing through the shunt resistors connected in parallel and/or third bond connection means. Cost savings are made through such an arrangement, since an additional shunt module can be dispensed with.

A further form of embodiment makes provision for the semiconductor assembly to comprise at least three electrically conductive connection means connected in parallel, which are embodied as shunt resistors and/or third bond connection means. Such connection means are inexpensive and space saving to implement. Connection means already present can be used in order to save additional installation space.

A further form of embodiment makes provision for the shunt resistors and/or third bond connection means to be connected in a materially-bonded manner to the second conductor track and the third conductor track of the substrate. The materially-bonded connection is able to be made for example by soldering or sintering. With wire bonding a material-bonded connection can be established by a friction welding method. Such connections are reliable and thus contribute to a longer service life of the semiconductor assembly.

A further form of embodiment makes provision for at least two electrically conductive connection means to differ in respect of their impedance. For example the at least two electrically conductive connection means differ in respect of their series resistance and/or their inductance. For example, with a complex impedance a switching frequency at which the semiconductor assembly is operated is included for the calculation. A symmetry is produced easily and reliably by the different impedances.

A further form of embodiment makes provision for the different impedances to be established by materials with different electrical conductivity and/or by a different conductor geometry. Through the use of materials with different electrical, conductivity connection means with identical geometry are able to be used, which makes possible an optimal utilization of the available installation space. Connection means with different conductor geometry, in particular length and/or cross section of the conductors, are able to be produced easily and at low cost.

A further form of embodiment makes provision for the second conductor track to be connected via at least three substantially identically embodied electrically conductive connection means to the third conductor track of the substrate, wherein a first electrically conductive connection means is at a first distance from a second electrically conductive connection means, wherein the second electrically conductive connection means is at a second distance from a third electrically conductive connection means and wherein the second distance is greater than the first distance. Symmetry is established easily and at low cost by different distances. In particular the division of current is able to be optimized flexibly for example as a function of an application of the semiconductor assembly.

A further form of embodiment makes provision for the semiconductor elements to be connected at an angle and asymmetrically with regard to a central longitudinal axis on the substrate. Through such an arrangement an optimization in respect of a removal of heat by spreading the heat and a division of current, for example by variation of line lengths, that have parasitic impedances is made possible.

A further form of embodiment makes provision for the semiconductor elements to have long edges, wherein the distances of the respective long edges of the semiconductor elements increase towards the second conductor track. Through such an arrangement greater spread of heat and an improved production of current symmetry, in particular load current symmetry, is able to be achieved.

A further form of embodiment makes provision for the semiconductor elements to comprise transistors connected in parallel, wherein the long edges and/or the first bond connection means of the first transistor form a first angle with the long edges and/or first bond connection means of the second transistor, wherein the long edges and/or the first bond connection means of the third transistor form a second angle with the long edges and/or first bond connection means of the second transistor. Through such an arrangement a greater spread of heat and an improved production of current symmetry, in particular load current symmetry, is able to be achieved.

A further form of embodiment makes provision for the first angle to differ from the second angle. The angles differ in particular in their amount. Through such an arrangement a greater spread of heat and an improved production of current symmetry, in particular load current symmetry, is able to be achieved.

The invention will be described in greater detail and explained below with the aid of the exemplary embodiments shown in the figures. In the figures

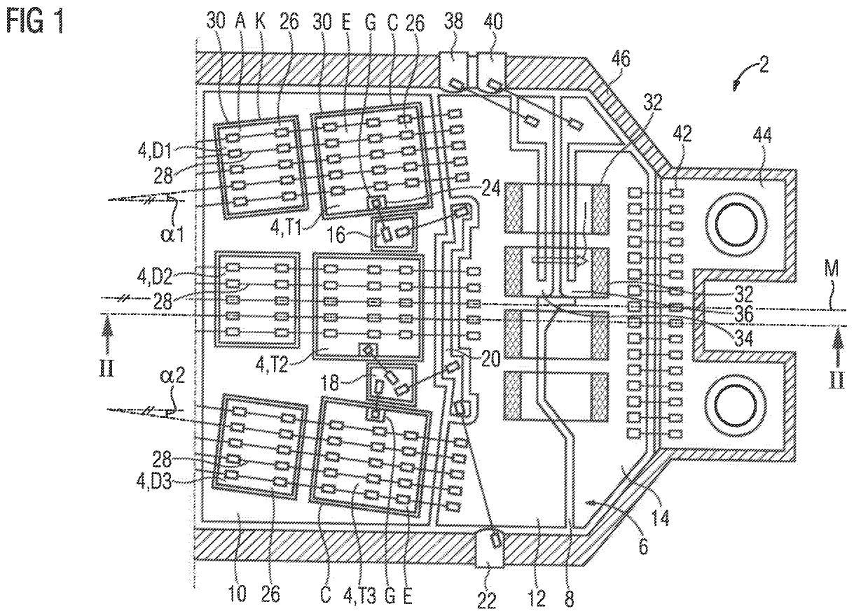

FIG. 1 shows a schematic diagram of a first form of embodiment of a semiconductor assembly in an overhead view,

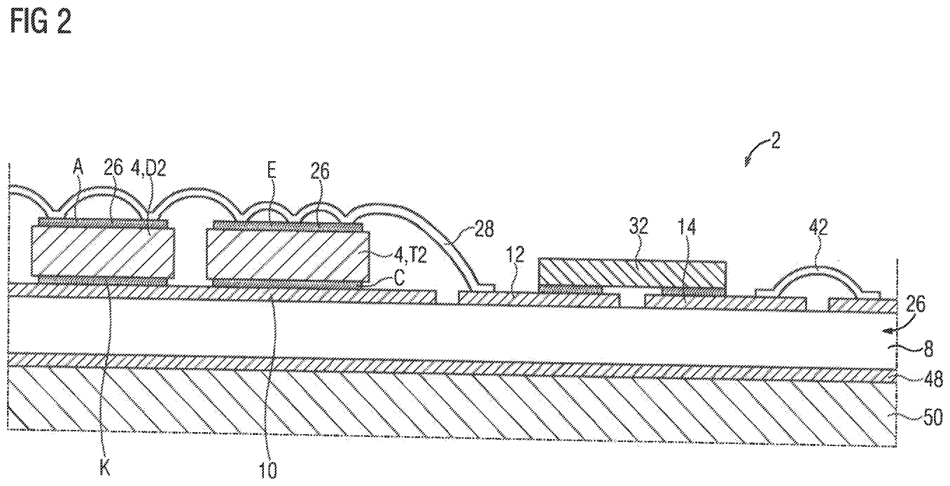

FIG. 2 shows a schematic diagram of a first form of embodiment of a semiconductor assembly in a longitudinal section,

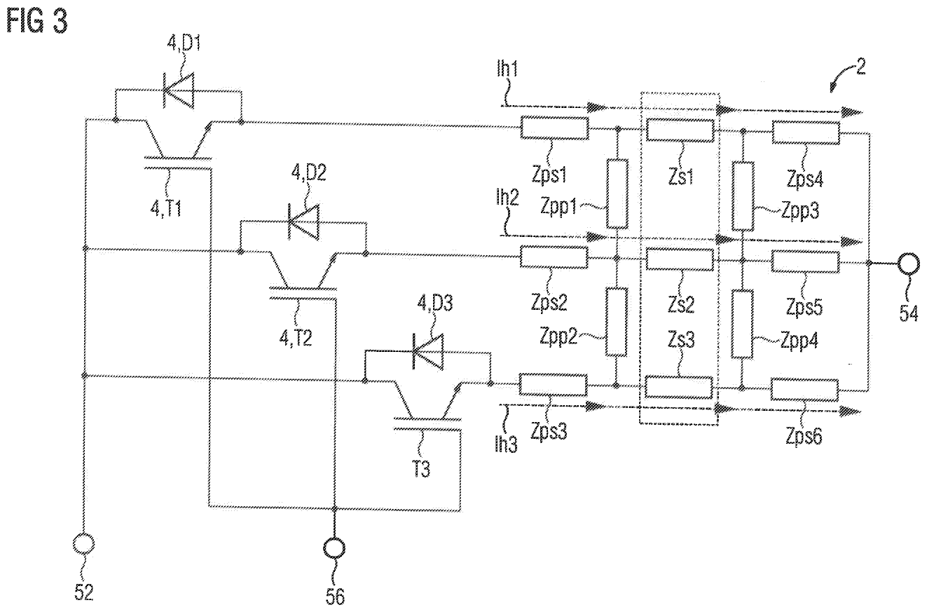

FIG. 3 shows a simplified circuit diagram of a first form of embodiment of a semiconductor assembly,

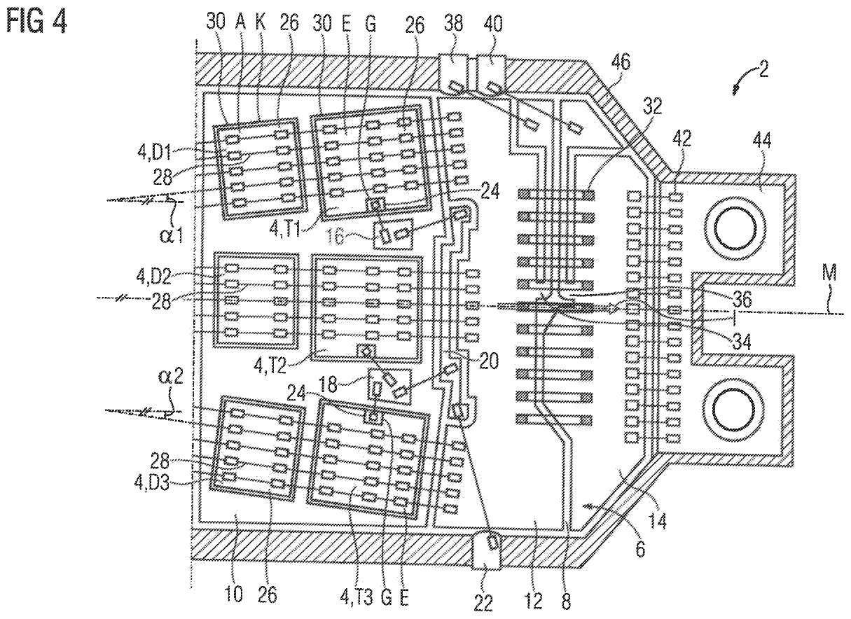

FIG. 4 shows a schematic diagram of a second form of embodiment of a semiconductor assembly in an overhead view,

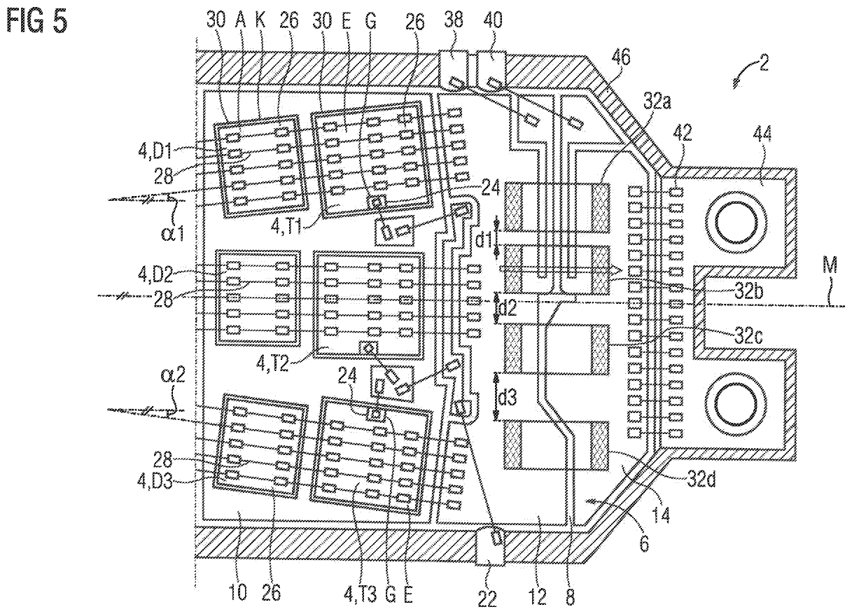

FIG. 5 shows a schematic diagram of a third form of embodiment of a semiconductor assembly in an overhead view and

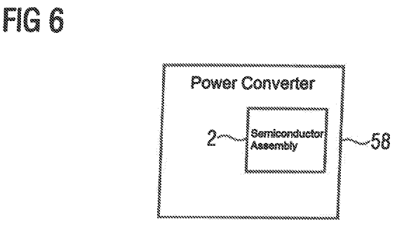

FIG. 6 shows a schematic diagram of a power converter.

The exemplary embodiments explained below involve preferred forms of embodiment of the invention. In the exemplary embodiments the components of the forms of embodiment described each represent individual features of the invention to be considered independently of one another, which also further develop the invention in each case independently of one another and are thus also to be seen, individually or in a combination other than the one described, as an element of the invention. Moreover the forms of embodiment described are also able to be supplemented by further features of the invention already described.

The same reference characters have the same meaning in the various figures.

FIG. 1 shows a schematic diagram of a first form of embodiment of a semiconductor assembly 2 in a view from above, which comprises semiconductor elements 4, which are contacted on an insulating substrate 6. The semiconductor elements 4 comprise transistors T1, T2, T3 with antiparallel diodes D1, D2, D3, wherein the semiconductor elements 4 are connected in parallel. The transistors T1, T2, T3 are embodied by way of example as Insulated-Gate Bipolar Transistors (IGBTs). As an alternative the transistors T1, T2, T3 can be embodied as other transistor types such as field effect transistors or bipolar transistors. The transistors T1, T2, T3 each have a control connection, which is embodied as gate connection G, as well as load connections, which are embodied as collector connection C and emitter connection E. The diodes D1, D2, D3 each have load connections, which are embodied as anode A and cathode K.

The substrate 6 comprises a layer of dielectric material 8, which for example contains a ceramic material, in particular aluminum nitride or aluminum oxide. Conductor tracks 10, 12, 14, 16, 18, 20 insulated electrically from one another are arranged on the layer of dielectric material 8. The collector connections C of the transistors T1, T2, T3 and the cathodes K of the diodes D1, D2, D3 connected in a materially-bonded manner to a first conductor track 10 of the substrate 6. The materially-bonded connection is established for example by soldering or sintering. The gate connections G have metallic control contact surfaces 24, which are wired via gate conductor tracks 16, 18 20 to a gate electrode 22. The emitter connections E as well as the anodes A have metallic contact surfaces 26, which are connected, via for example five first bond connection means 28, to a second conductor track 12. The first bond connection means 28 of the respective transistors T1, T2, T3 and antiparallel diodes D1, D2, D3, which are embodied for example as bond wires or bond tapes, are arranged substantially in parallel to one another.

The semiconductor elements 4 are arranged at an angle and asymmetrically with regard to a central longitudinal axis M on the first conductor track 10, wherein the distances of the respective long edges 30 of the semiconductor elements 4 towards the second conductor track 12 increase. In particular the respective first bond connection means 28 are arranged parallel to the long edges 30. The long edges 30 and/or the first bond connection means 28 of the first transistor T1 form a first angle α1 with the long edges 30 and/or first bond connection means 28 of the second transistor T2. The long edges 30 and/or the first bond connection means 28 of the third transistor T3 form a second angle α2 with the long edges 30 and/or first bond connection means 28 of the second transistor T2. In particular the first angle α1 differs from the second angle α2. Through such an arrangement a maximum spread of heat on the substrate 6 is achieved.

The second conductor track 12 is connected via electrically conductive connection means 32 to the third conductor track 14 of the substrate 6. The electrically conductive connection means 32 in FIG. 1 are embodied by way of example as shunt resistors connected in parallel. The shunt resistors are arranged transverse to a current direction. The second conductor track 12 and the third conductor track 14 each have a measurement tap 34, 36. The measurement taps 34, 36 are configured for detection of a current through the shunt resistors connected in parallel and are wired to measurement electrodes 38, 40. The measurement taps 34, 36 preferably lie at a position that is always equipped with a component, in particular a shunt resistor, which corresponds to a target value for the measurement. Thus a reliable and precise measurement can be ensured. With an even number of possible positions the measurement taps 34, 36 are each able to be divided between two components. Via second bond connection means 42 the third conductor track 14 is connected to a connection element 44.

The transistors T1, T2, T3 with the diodes D1, D2, D3 connected in an antiparallel manner each form a current path with a current path impedance to the connection element 44. Three different current paths can be formed inter alia by the three transistors T1, T2, T3 connected in parallel shown in FIG. 1 and/or through different switching states. The current path impedance can be composed of the respective impedances, in particular resistances, of the semiconductor elements 4, of the bond connection means 28, 42 in the current path, the conductor tracks 10, 12, 14 on the substrate 6, the shunt resistors and transitions, for example to connection element 44. Through a different dimensioning of the electrically conductive connection means 32 current path impedances of the respective current paths are balanced. In FIG. 1 the at least two electrically conductive connection means 32 differ in respect of their series resistances. Different series resistances are established by the use of materials with different electrical conductivity and/or by a different conductor geometry, in particular length and/or cross section of the conductor. Thus the overall resistance of the respective current paths are made symmetrical, which leads to an even heating of the semiconductor elements 4, in particular transistors T1, T2, T3. The semiconductor elements 4 and the substrate 6 are arranged in a housing 46, in particular a plastic housing.

FIG. 2 shows a schematic diagram of a first form of embodiment of a semiconductor assembly 2 in a longitudinal section. The substrate is connected via a continuity of the metallization 48, in particular in a materially-bonded manner, for example by a soldered or sintered connection, to a heatsink 50. The further embodiment of the semiconductor assembly 2 in FIG. 2 corresponds to that shown in FIG. 1.

FIG. 3 shows a simplified circuit diagram of a first form of embodiment of a semiconductor assembly 2. The transistors T1, T2, T3 are connected on the collector side to a first load connection 52 and on the emitter side to a second load connection 54, while the gates are connected to a control connection 56. The transistors T1, T2, T3 each form a main current path Ih1, Ih2, Ih3. The main current paths Ih1, Ih2, Ih3 each have a shunt resistor impedance Zs1, Zs2, Zs3, which depend on the dimensioning of the respective shunt resistors and on their arrangement. Further, parasitic series impedances Zps1, Zps2, Zps3 and parallel impedances Zpp1, Zpp2 are embodied upstream of the shunt resistors and parasitic series impedances Zps4, Zps5, Zps6 and parallel impedances Zpp3, Zpp4 are embodied downstream of the shunt resistors, which in particular are dependent on structure and geometry. Through a different dimensioning of the shunt resistor impedances Zs1, Zs2, Zs3, the impedances of the main current paths Ih1, Ih2, Ih3 are balanced, which leads to an even heating of the semiconductor elements 4, in particular transistors T1, T2, T3.

FIG. 4 shows a schematic diagram of a second form of embodiment of a semiconductor assembly 2 in a view from above. The electrically conductive connection means 32 are embodied as bond connection means, in particular as bond wires or bond tapes. The at least two bond connection means differ in respect of their impedance, in particular series impedance. The different impedances are established through the use of materials, in particular alloys, with different electrical conductivity and/or by a different conductor geometry. The conductor geometry is varied by a different length and/or by a different cross section of the bond connection means. The further embodiment of the semiconductor assembly 2 in FIG. 4 corresponds to that shown in FIG. 1.

FIG. 5 shows a schematic diagram of a third form of embodiment of a semiconductor assembly 2 in a view from above. For example electrically conductive connection means 32a, 32b, 32c, 32d are embodied as substantially identically embodied shunt resistors, which are arranged in such a way that the current path impedances of the respective current paths are substantially balanced. A first electrically conductive connection means 32a is at a first distance d1 from a second electrically conductive connection means 32b, wherein the second electrically conductive connection means 32b is at a second distance d2 from a third electrically conductive connection means 32d and wherein the third electrically conductive connection means 32c is at a third distance d3 from a fourth electrically conductive connection means 32d. The distances d1, d2, d3 are different from one another. For example the first distance d1 is smaller than the second distance d2 and the second distance d2 is smaller than the third distance d3. The effect of these distances is that a current path impedance is reduced by the arrangement of the shunt resistors in the area of the first transistor T1 by comparison with the impedance in the area of the second and third transistor T2, T3. Through such an arrangement an increased wiring impedance and/or supply line impedance of the first transistor T1 inter alia are able to be balanced, so that an overall resistance of the respective current paths is made symmetrical.

FIG. 6 shows a schematic diagram of a power converter 58, which comprises a semiconductor assembly 2 for example.

In summary the invention relates to a semiconductor assembly 2 with at least two semiconductor elements 4, that are in particular connected in parallel, an insulating substrate 6 and to a connection element 44, wherein the substrate 6 has conductor tracks 10, 12, 14 electrically insulated from one another, wherein the semiconductor elements 4 are connected, in particular in a materially-bonded manner, to a first conductor track 10 of the substrate 6 and in each case have at least one contact surface 26 on a side facing away from the substrate 6, wherein in each case at least one contact surface 26 of the semiconductor elements 4 is connected via first bond connection means 28 to the second conductor track 12 of the substrate 6, wherein the second conductor track 12 is connected via electrically conductive connection means 32, 32a, 32b, 32c, 32d to a third conductor track 14 of the substrate 6, wherein the third conductor track 14 is connected to the connection element 44, wherein a current path with a current path impedance is embodied in each case from the semiconductor elements 4 to the connection element 44. In order to obtain a longer service life and to make cost savings it is proposed that the electrically conductive connection means 32, 32a, 32b, 32c, 32d are dimensioned and/or arranged in such a way that the current path impedances of the respective current paths are substantially balanced.

1-14. (canceled)

15. A semiconductor assembly, comprising:
an insulating substrate comprising conductor tracks electrically insulated from one another;
a connection element;
at least two semiconductor elements connected to one another and connected to a first one of the conductor tracks of the substrate, said at least two semiconductor elements including each on a side facing away from the substrate a contact surface, wherein a current path with a current path impedance is embodied from each of the at least two semiconductor elements to the connection element;
a first bond connector designed to connect the contact surface to a second one of the conductor tracks of the substrate; and
electrically conductive connections connected in parallel and arranged transverse to a current direction to connect the second one of the conductor tracks of the substrate to a third one of the conductor tracks of the substrate, said third one of the conductor tracks of the substrate being connected to the connection element, said electrically conductive connections dimensioned and/or arranged in such a way that the current path impedances of the current paths from the at least two semiconductor elements to the connection element are substantially balanced, wherein the second one of the conductor tracks of the substrate and the third one of the conductor tracks of the substrate each have a measurement tap to detect a current through the electrically conductive connections.

16. The semiconductor assembly of claim 15, wherein the semiconductor elements are connected in parallel.

17. The semiconductor assembly of claim 15, wherein the semiconductor elements are connected in a materially-bonded manner to the first one of the conductor tracks of the substrate.

18. The semiconductor assembly of claim 15, further comprising a second bond connector designed to connect the third one of the conductor tracks of the substrate to the connection element.

19. The semiconductor assembly of claim 15, wherein a number of the electrically conductive connections is three, said three electrically conductive connection means being embodied as shunt resistors and/or as third bond connectors.

20. The semiconductor assembly of claim 19, wherein the shunt resistors and/or third bond connectors are connected in a materially-bonded manner to the second one of the conductor tracks and to the third one of the conductor tracks of the substrate.

21. The semiconductor assembly of claim 15, wherein at least two of the electrically conductive connections differ in respect of their impedance.

22. The semiconductor assembly of claim 21, wherein the different impedances are established by materials with different electrical conductivity and/or by a different conductor geometry.

23. The semiconductor assembly of claim 15, wherein the second one of the conductor tracks is connected via at least three substantially identically embodied ones of the electrically conductive connections to the third one of the conductor tracks of the substrate, with a first one of the at least three substantially identically embodied ones of the electrically conductive connections spaced at a first distance from a second one of the at least three substantially identically embodied ones of the electrically conductive connections, and with the second one of the at least three substantially identically embodied ones of the electrically conductive connections spaced from a third one of the at least three substantially identically embodied ones of the electrically conductive connections at a second distance which is greater than the first distance.

24. The semiconductor assembly of claim 15, wherein the at least two semiconductor elements are connected at an angle and asymmetrically with regard to a central longitudinal axis on the substrate.

25. The semiconductor assembly of claim 15, wherein the at least two semiconductor elements have long edges spaced from the second one of the conductor tracks of the substrate by distances which increase toward the second one of the conductor tracks of the substrate.

26. The semiconductor assembly of claim 25, wherein the at least two semiconductor elements comprise transistors connected in parallel, wherein the long edges and/or the first bond connector of a first one of the transistors form a first angle with the long edges and/or first bond connector of a second one of the transistors, and wherein the long edges and/or the first bond connector of a third one of the transistors form a second angle with the long edges and/or first bond connector of the second one of the transistors.

27. The semiconductor assembly of claim 26, wherein the first angle is different from the second angle.

28. A power converter, comprising a semiconductor assembly as set forth in claim 15.

29. A method for producing a semiconductor assembly, the method comprising:
forming an insulating substrate with conductor tracks that are electrically insulated from one another;
connecting at least two semiconductor elements to a first one of the conductor tracks of the substrate;
connecting a substrate-distal contact surface of each of the at least two semiconductor elements via a first bond connector to a second one of the conductor tracks of the substrate;
connecting the second one of the conductor tracks of the substrate via electrically conductive connections to a third one of the conductor tracks of the substrate;
connecting the third one of the conductor tracks of the substrate to a connection element;
forming a current path with a current path impedance from each of the at least two semiconductor elements to the connection element;
dimensioning and/or arranging the electrically conductive connections in such a way that the current path impedances of the current paths from the at least two semiconductor elements to the connection element are substantially balanced;
connecting the electrically conductive connections in parallel and transverse to a current direction; and
detecting a current through the electrically conductive connections via a measurement tap of the second one of the conductor tracks and a measurement tap of the third one of the conductor tracks of the substrate.

30. The method of claim 29, further comprising connecting the at least two semiconductor elements in parallel.

31. The method of claim 29, wherein the semiconductor elements are connected in a materially-bonded manner to the first one of the conductor tracks of the substrate.

32. The method of claim 29, wherein a number of the electrically conductive connections is three, and further comprising:
embodying the three electrically conductive connections as shunt resistors and/or as third bond connectors; and
connecting the shunt resistors and/or third bond connectors in a materially-bonded manner to the second one of the conductor tracks and the third one of the conductor tracks of the substrate.

33. A computer program product embodied on a non-transitory computer readable medium comprising commands that, when executed by a computer, cause the computer to simulate a behavior of a semiconductor assembly as set forth in claim 15.
